(19) United States
(12) Patent Application Publication
(10) Pub. No.: US 2025/0210844 A1
(43) Pub. Date: Jun. 26, 2025

(54) MM-WAVE SIGNAL POWER DIVIDER AND ANTENNA ARRAY

(71) Applicant: SAMSUNG ELECTRONICS CO., LTD., Suwon-si (KR)

(72) Inventors: Gennadiy Alexandrovich EVTYUSHKIN, Saratov (RU); Elena Aleksandrovna SHEPELEVA, Saratov (RU); Anton Sergeevich LUKYANOV, Saratov (RU)

(21) Appl. No.: 18/820,934

(22) Filed: Aug. 30, 2024

(30) Foreign Application Priority Data
Dec. 20, 2023 (RU) 2023134096

(51) Int. Cl. H01P 5/12; H03H 7/48; H04B 1/40

(52) U.S. Cl. CPC H01P 5/12; H03H 7/482; H04B 1/40

(57) ABSTRACT

The present disclosure relates to a 5G communication system or a 6G communication system for supporting higher data rates beyond a 4G communication system such as long term evolution (LTE). The present invention relates to an mm-wave signal power divider implemented on a PCB that includes an input arm, two output arms and a termination load embedded into the PCB, wherein each power divider arm includes a feedline having impedance Z0; each power divider output arm further includes a main power divider branch and an additional power divider branch; the main power divider branch connects the input arm feedline and the output arm feedline and has a length multiple of ˜λ_{ε}/4; the additional power divider branch extends from the point of connection of the main power divider branch with the output arm feedline to the symmetry plane of the termination load and has a length multiple of ˜λ_{ε}/2; additional power divider branches are connected in the symmetry plane of the termination load.

### CROSS-REFERENCE TO RELATED APPLICATION

This application is based on and claims priority under 35 U.S.C. § 119 to Russian Patent Application No. 2023134096 filed on Dec. 20, 2023, in the Russian Intellectual Property Office, the disclosure of which is incorporated by reference herein in its entirety.

### BACKGROUND

### 1. Field

The present invention relates to radio engineering, and more specifically, to an mm-wave signal power divider with embedded resonant contactless termination load, which can be used, for example, in multi-element antenna arrays comprising such power dividers.

### 2. Description of Related Art

Considering the development of wireless communication from generation to generation, the technologies have been developed mainly for services targeting humans, such as voice calls, multimedia services, and data services. Following the commercialization of 5G (5th-generation) communication systems, it is expected that the number of connected devices will exponentially grow. Increasingly, these will be connected to communication networks. Examples of connected things may include vehicles, robots, drones, home appliances, displays, smart sensors connected to various infrastructures, construction machines, and factory equipment. Mobile devices are expected to evolve in various form-factors, such as augmented reality glasses, virtual reality headsets, and hologram devices. In order to provide various services by connecting hundreds of billions of devices and things in the 6G (6th-generation) era, there have been ongoing efforts to develop improved 6G communication systems. For these reasons, 6G communication systems are referred to as beyond-5G systems.

6G communication systems, which are expected to be commercialized around 2030, will have a peak data rate of tera (1,000 giga)-level bps and a radio latency less than 100 μsec, and thus will be 50 times as fast as 5G communication systems and have the 1/10 radio latency thereof.

In order to accomplish such a high data rate and an ultra-low latency, it has been considered to implement 6G communication systems in a terahertz band (for example, 95 GHz to 3 THz bands). It is expected that, due to severer path loss and atmospheric absorption in the terahertz bands than those in mmWave bands introduced in 5G, technologies capable of securing the signal transmission distance (that is, coverage) will become more crucial. It is necessary to develop, as major technologies for securing the coverage, radio frequency (RF) elements, antennas, novel waveforms having a better coverage than orthogonal frequency division multiplexing (OFDM), beamforming and massive multiple input multiple output (MIMO), full dimensional MIMO (FD-MIMO), array antennas, and multiantenna transmission technologies such as large-scale antennas. In addition, there has been ongoing discussion on new technologies for improving the coverage of terahertz-band signals, such as metamaterial-based lenses and antennas, orbital angular momentum (OAM), and reconfigurable intelligent surface (RIS).

Moreover, in order to improve the spectral efficiency and the overall network performances, the following technologies have been developed for 6G communication systems: a full-duplex technology for enabling an uplink transmission and a downlink transmission to simultaneously use the same frequency resource at the same time; a network technology for utilizing satellites, high-altitude platform stations (HAPS), and the like in an integrated manner; an improved network structure for supporting mobile base stations and the like and enabling network operation optimization and automation and the like; a dynamic spectrum sharing technology via collision avoidance based on a prediction of spectrum usage; an use of artificial intelligence (AI) in wireless communication for improvement of overall network operation by utilizing AI from a designing phase for developing 6G and internalizing end-to-end AI support functions; and a next-generation distributed computing technology for overcoming the limit of UE computing ability through reachable super-high-performance communication and computing resources (such as mobile edge computing (MEC), clouds, and the like) over the network. In addition, through designing new protocols to be used in 6G communication systems, developing mechanisms for implementing a hardware-based security environment and safe use of data, and developing technologies for maintaining privacy, attempts to strengthen the connectivity between devices, optimize the network, promote softwarization of network entities, and increase the openness of wireless communications are continuing.

It is expected that research and development of 6G communication systems in hyper-connectivity, including person to machine (P2M) as well as machine to machine (M2M), will allow the next hyper-connected experience. Particularly, it is expected that services such as truly immersive extended reality (XR), high-fidelity mobile hologram, and digital replica could be provided through 6G communication systems. In addition, services such as remote surgery for security and reliability enhancement, industrial automation, and emergency response will be provided through the 6G communication system such that the technologies could be applied in various fields such as industry, medical care, automobiles, and home appliances.

The ever-increasing needs of users motivate rapid development of communication technologies. Advanced 5G and 6G communication networks supporting MIMO (Multiple input-multiple output) technology, which will feature higher performance characteristics such as high transmission rate and energy efficiency, are currently under active development.

New applications require a new class of radio systems capable of transmitting/receiving data/energy and able to adaptively change characteristics of radiated electromagnetic field. An important component of such systems are steerable antenna arrays, which find application in data transmission systems such as 5G (28 GHz), WiGig (60 GHz), Beyond 5G (60 GHz), 6G (subTHz), long-distance wireless power transmission (LWPT) (24 GHz), automotive radar systems (24 GHz, 79 GHz), etc.

Basic requirements to mm-wave antenna arrays used in the above fields include:
low loss and high gain;
ability of flexible steering of beam (direction of maximum radiation), i.e. beam scanning and focusing of radiated field in wide range of angles;
high isolation between channels;
low side lobes;
compact, inexpensive, simple architecture suitable for mass production.

Generally, control radio frequency integrated circuits (RFICs) have limited number of radio frequency channels. So, to increase the antenna aperture size and to ensure the required antenna gain, power distribution systems are used. Key element of these systems is a power divider that distributes power from single input RFIC channel to several antenna array elements.

One of the demands to power dividers is high isolation between arms, which is effectively realized in Willkinson-type power dividers using termination loads (resistors). An additional effect of the termination loads is that they suppress different parasitic components of signals (and their multiple reflections) received e.g., by antenna array side lobes. Termination load can be implemented as a matched load (“terminator”) or as a standard resistor. The termination loads can further suppress many reflected waves originating in the power dividers and causing distortion of the antenna array pattern, formation (or elevation) of antenna lobes, and deterioration of the antenna array. However, to date there are no commercial resistors and terminators for high frequencies (above 80 GHz), and standard components cannot be used because of high reactive parameters that disrupt the system. Moreover, small sizes of antenna arrays designed for 5G and 6G communication standards in principle limit the use of lumped resistors.

Currently, printed circuit board (PCB) technique is widely used in designing mm-wave radiators, since this technique permits the production of devices simple in design and easy to manufacture, highly precise, convenient to be integrated on a single substrate with other electronic components, and capable of achieving a wide band of operating frequencies. High topology density of state-of-the art devices requires placing power distribution circuits in inner layers of multilayer PCB, making it difficult to place any bulky components, such as hinged resistors, inside the PCB. Implementation of planar terminators in inner PCB layers is also problematic due to extremely tight tolerances for 5G and 6G communication equipment.

Current approaches to implementing termination load in multilayer PCB of antenna arrays (e.g., using SMD components or Embedded Component Packaging Tech) have a number of shortcomings:
large space to mount;
complicated structure;
expensive production;
long fabrication process;
infeasible to implement in AiP (Antenna-in-Package) structure;
inapplicable for frequencies higher 100 GHz;
internal film resistor cannot be used for organic dielectric since film resistors are implemented on ceramic substrates (Low Temperature Co-Fired Ceramic, LTCC) using special resistive compounds applied in high-temperature treatment.

U.S. Pat. No. 10,003,115 B2 discloses a terminator for inner PCB layers. In this disclosure, electromagnetic wave is received by a probe into waveguide and directed to lumped terminator on the PCB surface by means of outer stripline. However, this device requires a lumped resistor and its mounting, which is not possible for frequencies above 100 GHz.

U.S. Pat. No. 4,737,747 discloses a process of assembling a terminator for inner PCB layers. Absorbing resistive element is mounted on one side of first PCB, and a feedline is provided on top side of the other PCB. Then both PCBs are assembled together. However, this structure has to be assembled from two PCBs, which significantly impairs the alignment precision.

Russian Patent Publication No. 2,796,642 C1 discloses a termination load comprising a portion of at least one feedline, an intermediate patch, a top resonator patch surrounded by resistive material. By choosing the top patch size, absorption of excited electromagnetic energy by resistive material is ensured. Moreover, the patches are excited by excitation probe. However, the document discloses layout of elementary termination load, but is silent about specific aspects of using the termination load as a component of power dividers.

U.S. Patent Publication No. 2021/0091463 A1 discloses a stripline feed distribution system (feedline) with embedded resistor for mm-wave applications. The feed distribution system comprises power dividers that include signal striplines and a resistive element for absorbing energy in the form of a resistive layer on internal PCB layer. This system requires a galvanic contact between signal lines and the resistive element. Matching in the divider is provided by optimization of the line widths. However, coating of internal PCB layers by resistive layer is more difficult than coating of external layers. Coating on internal layers influences PCB thickness. In addition, matching by means of adjusting the line width only is not effective because it doesn't take into account the phase of signals reflected from the resistive element, which is controlled by the line length. This can cause additional loss and parasitic reflections in the antenna array feeding.

Thus, there is a need in the art for a compact, reliable, easy-to-manufacture and efficient power divider for antenna array, and an antenna array having high characteristics, including low side lobes and high efficiency factor, which has a positive effect on the antenna array performance (signal transfer speed and reliability).

### SUMMARY

The present invention is aimed to overcome at least some of the above challenges.

One aspect of the present invention provides a mm-wave signal power divider implemented on PCB and including an input arm, two output arms and a termination load embedded into the PCB, wherein each power divider arm is located on inner PCB layer and includes a feedline having impedance Z0; each power divider output arm further includes a main power divider branch and an additional power divider branch; the main power divider branch connects the input arm feedline and the output arm feedline and has a length multiple of ˜λ_{ε}/4, where λ_{ε} is the wavelength in the feedline of the mm-wave device, with account of dielectric parameters of the PCB materials; the additional power divider branch extends from the point of connection of the main power divider branch with the output arm feedline to the symmetry plane of the termination load and has a length multiple of ˜λ_{ε}/2; additional power divider branches are connected in the symmetry plane of the termination load; the termination load is disposed above an exciting feedline, which represents a portion of the connected additional power divider branches, and includes an intermediate slot radiator placed orthogonally to the exciting feedline between the layer where the exciting feedline is located and the outer PCB layer, and a power absorbing element located on said outer PCB layer; the symmetry plane of the termination load is arranged longitudinally to the intermediate slot radiator; the exciting feedline and the intermediate slot radiator are coupled via electromagnetic coupling.

In one embodiment of the power divider, the power absorbing element includes a resonator patch, a resistive material surrounding the resonator patch, a metal layer coplanar with the resonator patch, and wherein the resistive material fills the gap between the resonator patch and the coplanar metal layer, and the resonator patch and the intermediate slot radiator are coupled via electromagnetic coupling.

In another embodiment of the power divider, the resistive material in the gap between the resonator patch and the coplanar metal layer is a resistive film.

In another embodiment of the power divider, the size of the resonator patch is less than ˜λ/2\sqrt{ε}, where ε is the permittivity of the PCB substrate, and λ is the wavelength in free space.

In another embodiment of the power divider, the power absorbing element includes a resonator patch, a metal layer coplanar with the resonator patch, and a bulky radio-absorbing material or radio-absorbing coating applied on top of the resonator patch and the coplanar metal layer and configured to absorb the energy radiated by the resonator patch, wherein the resonator patch and the intermediate slot radiator are coupled via electromagnetic coupling.

In another embodiment of the power divider, the power absorbing element includes a bulky radio-absorbing material or radio-absorbing coating applied to the outer PCB layer above the intermediate slot radiator and configured to absorb the energy radiated by the intermediate slot radiator.

In another embodiment of the power divider, the radio-absorbing coating is a radio-absorbing paint or a radio-absorbing adhesive.

In another embodiment of the power divider, the size of the resonator patch is ˜λ/2\sqrt{ε}.

In another embodiment of the power divider, the termination load is surrounded over the perimeter by a plurality of interlayer plated holes (VIA), the distance between which does not exceed ˜λ/4\sqrt{ε}.

In another embodiment of the power divider, the length of the main power divider branches is ˜λ_{ε}4, and the length of the additional power divider branches is ˜λ_{ε}/2.

In another embodiment, the power divider is symmetrical with respect to the symmetry plane of the termination load.

In another embodiment of the power divider, each additional power divider branch has impedance Z0, and the termination load has impedance 2*Z0.

In another embodiment of the power divider, the intermediate slot radiator is in the form of a rectangular slot with length ˜λ/2\sqrt{ε} and width ˜λ/10\sqrt{ε}.

In another embodiment of the power divider, the intermediate slot radiator is H-shaped.

In another embodiment, the power divider is configured to provide non-uniform power distribution with the ratio A=P2/P3, where P2 and P3 are powers of signals on the power divider output arms, and the power divider branches have the impedance values:

$$Z 2 = \frac{1 + A}{\sqrt{2} A} Z 0 ,$$

$$Z 3 = \frac{1 + A}{\sqrt{2}} Z 0 ,$$

$$Z 4 = Z 5 = \sqrt{2} * Z 0 ,$$

where Z4 and Z5 are the impedance values of the main power divider branches, and Z2 and Z3 are the impedance values of the additional power divider branches; wherein the impedance of the power divider branches is set by specifying the width of the power divider branches.

A second aspect of the present invention provides an antenna array including antenna elements connected through a power distribution system comprising mm-wave signal power dividers according to the present invention, with a control circuit.

The present invention ensures high efficiency of a millimeter and sub-millimeter wave antenna array, more particularly, low side lobes of the radiation pattern, expands the scanning sector of the antenna array, and increases reliability and speed of wireless signal transmission by using, in the power distribution network, efficient power dividers with embedded absorption loads having compact dimensions, and simple and reliable architecture.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

The present disclosure is further explained by a description of various embodiments with references to the accompanying drawings, in which:

FIG. 1 illustrates a structure of an antenna array with power dividers (above) and a structure of mm-wave signal power divider with embedded termination load (below) in accordance with an embodiment of the present disclosure.

FIGS. 2A and 2B illustrate a simplified side cross-section (FIG. 2A) and top view (FIG. 2B) of a termination load structure in an mm-wave signal power divider in accordance with an embodiment of the present disclosure.

FIG. 3 illustrates an equivalent circuit of the mm-wave signal power divider in accordance with an embodiment of the present disclosure.

FIGS. 4A and 4B illustrate a schematic view of operating modes of a termination load for anti-phase signals on ports 2, 3 (FIG. 4A) and for in-phase signals on ports 2, 3 (FIG. 4B) in accordance with an embodiment of the present disclosure.

FIGS. 5A and 5B illustrate an equivalent circuit of the mm-wave signal power divider for operating modes of the termination load for anti-phase signals on ports 2 and 3 (FIG. 5A) and for in-phase signals on ports 2 and 3 (FIG. 5B) in accordance with an embodiment of the present disclosure.

FIG. 6 illustrates a view of energy accumulation process in a resonator patch in accordance with an embodiment of the present disclosure.

FIG. 7 illustrates a possible alternative shape of an intermediate slot radiator in accordance with an embodiment of the present disclosure.

FIG. 8 illustrates possible shapes of a resonator patch in accordance with alternative embodiments of the present disclosure.

FIG. 9 illustrates a side view of a PCB portion comprising a termination load in accordance with an alternative embodiment of the present disclosure.

FIG. 10 illustrates a side view of a PCB portion comprising a termination load in accordance with another alternative embodiment of the present disclosure.

FIG. 11 illustrates an mm-wave signal power divider in accordance with an alternative embodiment of the present disclosure.

### DETAILED DESCRIPTION

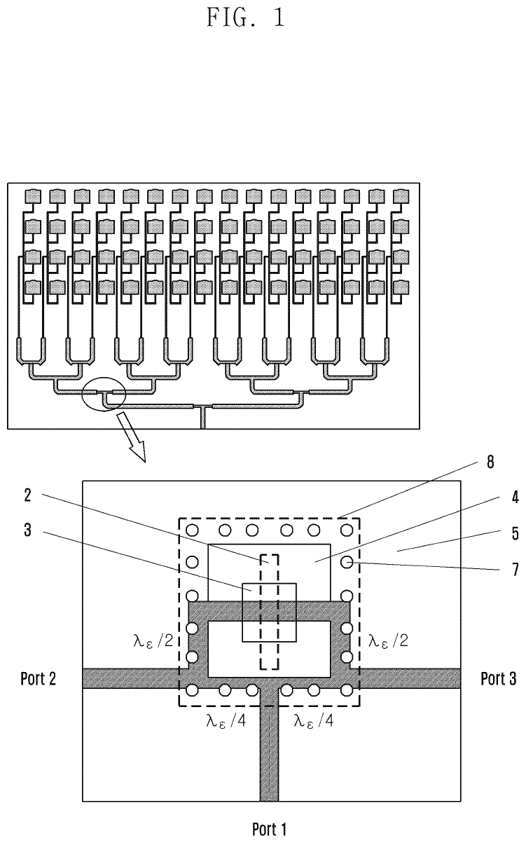

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

Embodiments of the invention are not limited to those described herein, other embodiments will become apparent to the person skilled in the art based on the information provided in the description and the prior art knowledge that are within the idea and scope of the invention.

Referring now to FIG. 1, an antenna array in accordance with an embodiment of the present disclosure comprises a plurality of antenna elements connected through a power distribution system including a plurality of power dividers (such as a circled one). Bottom part of FIG. 1 illustrates in detail a structure of an mm-wave signal power divider with an embedded termination load in accordance with an embodiment of the present disclosure.

The antenna array is implemented on a printed circuit board (PCB). Antenna elements comprise patch radiators to which signals from a control circuit (radio-frequency integrated circuit, RFIC) are transmitted via feedlines and power dividers. The signal transmission from the control circuit to the antenna elements is typical of the antenna array transmission operation. It should be apparent to the person skilled in the art that the antenna array may also receive signal from the outside, and then signal direction in the antenna array will be reversed—from the antenna elements to the control circuit.

The antenna array implemented on PCB makes its manufacture easier. In addition, the printed antenna structure can be easily modified to the required PCB configuration.

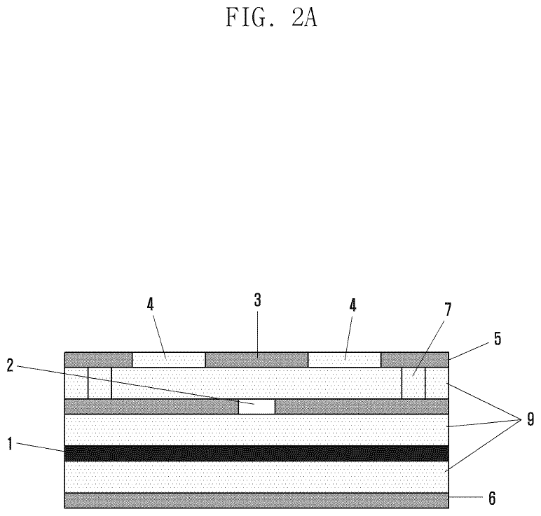

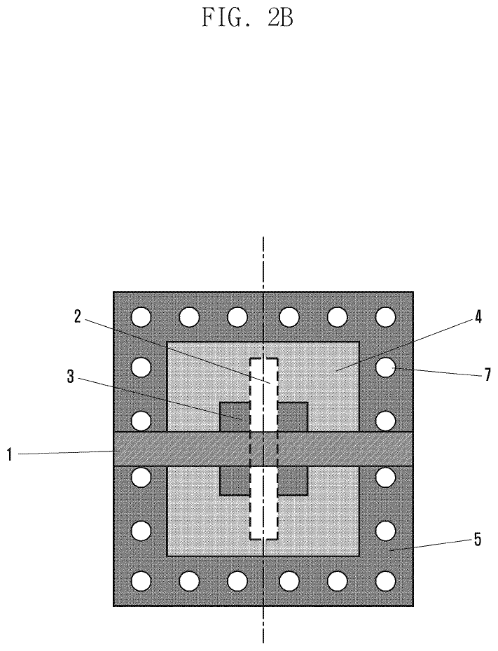

Referring further to FIGS. 1 and 2, an mm-wave signal power divider with a termination load embedded in PCB in accordance with an embodiment of the present disclosure is described.

The mm-wave signal power divider (hereinafter referred to as power divider for simplicity) is implemented on inner PCB layer and includes three arms (one input and two output) and a termination load integrated into the PCB. Each power divider arm is disposed on the Inner PCB layer and includes a feedline with impedance Z0. Each power divider output arm further includes a main power divider branch and an additional power divider branch. In the simulation, it can be assumed that the power divider branches are connected to antenna ports via feedlines with impedance Z0. When signal is transmitted from the control circuit to the antenna elements in FIG. 1, port 1 (first port) is the input port for the power divider, and port 2 (second port) and port 3 (third port) are the output ports. When signal is transmitted from the antenna elements to the control circuit, the ports (as well as the power divider arms) are reversed, i.e., port 1 is the output port, and port 2 and port 3 are the input ports, and the power divider itself acts as an adder.

In accordance with the present disclosure, the input arm feedline is connected to feedline of each of the output arms by the divider main branches, each of the branches having a length multiple of ˜λ_{ε}/4, where λ_{ε} is the wavelength in the feedline (feeder line) of the mm-wave device, taking into account dielectric parameters of the PCB materials.

From the point of connection of the main divider branch with the output arm feedline to the symmetry plane of the termination load (8), an additional divider branch extends, which has a length multiple of ˜λ_{ε}/2. Similarly, from the point of connection of the other main divider branch with the other output arm feedline to the symmetry plane of the termination load, another additional divider branch extends, which has a length multiple of ˜λ_{ε}/2. Thus, the additional divider branches are connected in the symmetry plane of the termination load.

In one embodiment, the length of the main divider branches is ˜λ_{ε}/4 and the length of the additional divider branches is ˜λ_{ε}/2.

FIGS. 2A and 2B illustrate a simplified view of a termination load structure with power divider additional branches shown only partially. The termination load (8) embedded into a PCB in accordance with an embodiment of the present disclosure depicted in FIGS. 1 and 2 is disposed above an exciting feedline (1), which is a portion of the connected additional power divider branches, and includes an intermediate slot radiator (2) arranged orthogonally to the exciting feedline (1) and a power absorbing element placed on the outer PCB layer. The exciting feedline (1), as well as the power divider arms, is disposed on the inner layer in the PCB between a bottom ground layer (6) and a top external layer on which the power absorbing element is placed. The intermediate slot radiator (2) is arranged in the PCB between the layer in which the exciting feedline (1) is located and said top external layer.

In the above examples, direction terms (such as “above”, “up”, “below”, “down”, “up”, “down”, etc.) are used only for the convenience of referring to the accompanying drawings.

The power absorbing element includes a resonator patch (3), a resistive material (4) surrounding the resonator patch (3), a metal (ground) layer (5) coplanar with the resonator patch (3), the resistive material (4) filling the gap between the resonator patch (3) and the coplanar metal layer (5).

The exciting feedline (1), the intermediate slot radiator (2) and the resonator patch (3) are coupled via electromagnetic coupling.

Thus, the intermediate slot radiator (2) has no galvanic contact with the exciting feedline (1) and with the power absorbing element of the termination load (8), i.e., the termination load (8) has a contactless structure.

In one embodiment, the termination load (8) and the power divider as a whole are symmetrical with respect to the symmetry plane located longitudinally to the intermediate slot radiator (2). The symmetry plane is perpendicular to the PCB plane.

The resistive material (4) in this embodiment comprises a resistive film.

Dielectric layers (9) are disposed between conductive PCB layers.

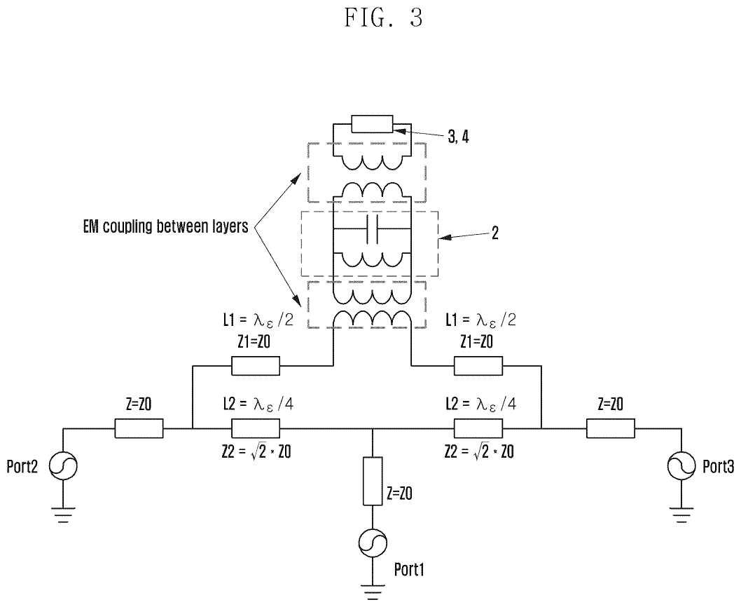

Additional divider branches provide additional space for termination load. As can be seen from the equivalent circuit of the voltage divider in FIG. 3, each additional divider branch has length L1˜λ_{ε}/2 and impedance Z0, i.e., the same impedance of feedlines from all ports. The termination load has impedance 2*Z0.

Hereinafter, operation of the power divider is described for the case where signals are fed to ports 2 and 3.

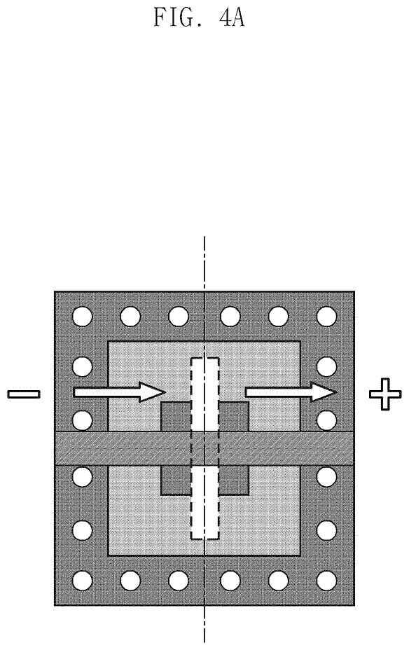

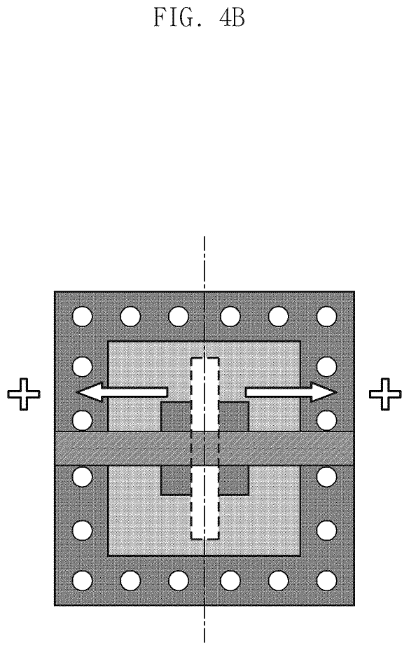

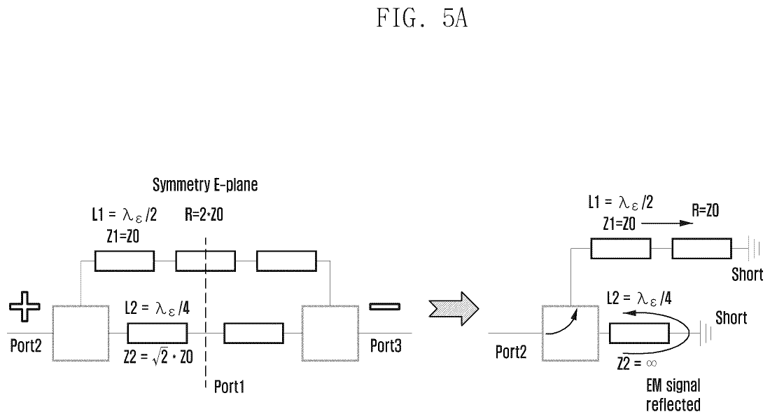

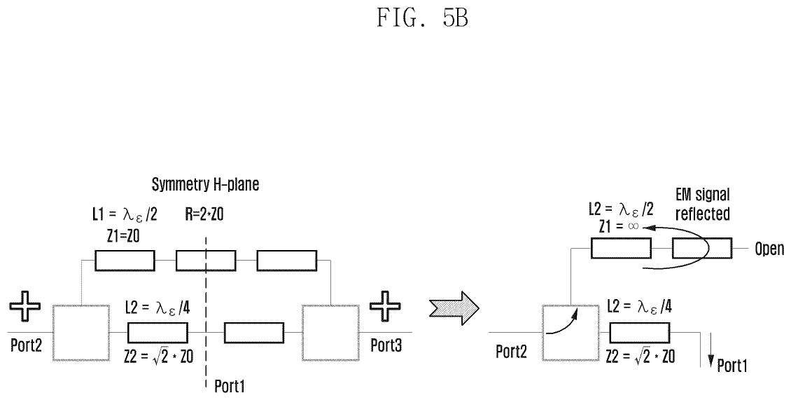

The power divider described above enables the device to operate in two opposite states:
loading mode for anti-phase signals on ports 2 and 3 (FIGS. 4a, 5a), which corresponds to the extreme case of receiving maximum anti-phase (180 degrees) signals. This mode ensures absorption of parasitic reflections in the device path. Meanwhile, the intermediate state, when the phase difference is smaller, will be realized on the same principle (described below);
reflecting mode for in-phase signals on ports 2 and 3 (FIGS. 4b, 5b). This mode corresponds to reception/transmission of a useful signal having no parasitic antiphase.

In the loading mode (FIGS. 4a, 5a), anti-phase signals are fed to the power divider ports 2 and 3. In this case, main power divider branch L2 represent short stub loop. Due to length L2˜λ_{ε}/4, its impedance is Z2=∞ (virtual electric “wall” is formed in symmetry E-plane). In the case of circuit symmetry, it can be substantially simplified by a (conditional) division along the axis of symmetry with an ideal electric or magnetic plane. Choice of the plane property (E or H) depends on the phase of the signals fed to symmetrical ports. If the signals are in-phase, the plane will be H (magnetic), if anti-phase, the plane will be E (electrical). At the division points, corresponding states of the separated parts of the circuit will be formed. For example, plane E will form short mode (short) (Z=0), while plane H, on the contrary, will form open mode (open) (Z=∞). The wave is completely reflected from such division points, and the reflected signal phase will be 0 for H plane (open) and 180 degrees for E plane (short), respectively, repeating at interval λ_{ε}/2. Moreover, at distance λ_{ε}/4 from the boundary, the impedance changes to the opposite. Therefore, one-directed electric fields are generated in the termination load (FIG. 4a). The power divider additional branch L1 is matched completely because the termination load is symmetrical with respect to the symmetry plane, and is divided in half. Therefore, all power from port 2 is transferred to the half of the termination load (FIG. 5a) and absorbed in resistive film (as described in more detail below). Similarly, power from port 3 is transferred to the other half of the termination load and absorbed in resistive film. As each part of the virtually divided load has impedance Z0, they are both matched with lines L1.

In the reflecting mode (FIGS. 4b, 5b), in-phase signals are fed to ports 2 and 3 of the power dividers. Additional branch L1 of the power divider represents open stub because the slot radiator blocks the termination load (virtual magnetic “wall” is formed in symmetry H-plane). In this case, the impedance of the additional branch is Z1=∞ at the point of its connection with line L2 due to its length L1˜λ_{ε}/2. Opposite electric fields are formed in the termination load (FIG. 4b). Energy from ports 2 and 3 is completely reflected from the termination load, because the slot radiator cannot be excited by opposite directed fields. Since the L1 impedance is Z1=∞ at the point of connection with L2, it has no shunt effect. Therefore, all power from port 2 proceeds to port 1 through main branch L2 of the power divider (FIG. 5b). Similarly, the signal power from port 3 also proceeds to port 1 through the main branch.

Intermediate mode, where incoming signals are not exactly in-phase or anti-phase, is also provided in the power divider as a transient state between these two extreme states. In this case, incoming signals can be divided into in-phase and anti-phase components, each passing through the power divider according to the modes described above. This mode typically occurs in the power divider when signals arrive at antenna array elements with a phase shift, or when phase shift of signals between different divider inputs occurs due to signal reflections and distortions on non-uniformities in the feedline structure of the antenna array power distribution system.

In the loading mode, signal power from port 2 and port 3 excites the intermediate slot radiator (2) through the exciting feedline (1). The intermediate slot radiator (2) is electromagnetically coupled to the resonator patch (3), which is surrounded by a resistive film (4). Power concentrated in the patch (3) is absorbed by the resistive film (4). Therefore, power of the anti-phase signals is absorbed by the termination load (8).

The exciting feedline (1) is contactlessly coupled to the intermediate slot radiator (2). The exciting feedline (1) excites the resonator patch (3) through the intermediate slot radiator (2) via electromagnetic coupling. Therefore, the present disclosure does not require a conductive interlayer plated hole (VIA) used in conventional systems to transfer power between feedline on inner PCB layers and termination load.

An equivalent circuit of contactless connection of the exciting feedline (1), the intermediate slot radiator (2) and the resonator patch (3), shown in FIG. 3, depicts the operating principle of the inventive termination load configuration. The intermediate slot radiator (2) is electromagnetically coupled to the exciting feedline (1) and the resonator patch (3). This electromagnetic coupling is equivalent to operation of a transformer and does not require galvanic coupling. Resistor in the equivalent circuit in FIG. 3 denotes the resonator patch (3) and the resistive film (4) that absorbs energy. Due to their optimal size, the intermediate slot radiator (2) and the resonator patch (3) with the resistive layer (4) are well matched, and as a result, electromagnetic energy from the exciting feedline (1) is absorbed completely, since the resonator patch (3) is a low-Q resonator due to the presence of the resistive film (film resistor).

In accordance with one embodiment, the resistive film (4) is based on a low-conductivity material, such as, for example, “Aquadag E”, having a resistivity of about 1000 Ohms/□ (ohms per square). In one embodiment, thickness of the resistive film (4) is in the range of 5-30 μm. This thickness is commensurate with thickness of the outer PCB layer plating, which facilitates the process of applying it to the gap between the resonator patch (3) and the coplanar metal layer (5). Due to the resonance effect, described in more detail below, a large amount of energy is accumulated around the resonator patch (3). Maximum voltage is distributed at the patch (3) edges perpendicular to the exciting feedline (1). The voltage between the patch (3) edge and the metal ground layer (5) causes current flow in the resistive film (4) and conversion of the flowing current into thermal energy by the resistive film (4).

In conventional termination loads, the operating principle relies on the absorption of electromagnetic energy as dissipative losses in low-conductivity materials deposited on a ceramic substrate that can withstand high-temperature treatment required for their application (firing treatment). The present invention, on the contrary, involves depositing and drying the resistive material at a low temperature, allowing its use for low-cost organic PCB substrates.

In addition, resistive film (4) of the present invention has no parasitic reactance, and therefore does not require matching circuits or components that need additional space.

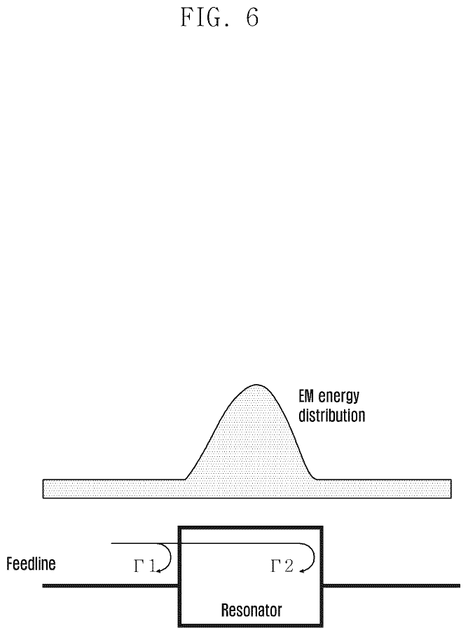

Referring further to FIG. 6, the principle of energy absorption by a termination load based on the resonator operation is described.

In accordance with the present invention, the resonator patch (3) represents a resonator accumulating energy from the intermediate slot radiator (2). For accumulation of electromagnetic energy by the resonator, the following condition is to be met:

G1=−G2,
where G1 is the reflection coefficient of the resonator's first edge, and G2 is the reflection coefficient of the resonator's second edge.

To meet the above condition, the required longitudinal size of the resonator (usually half the wavelength in the resonator) and the size of connection line with the resonator are specified.

Energy accumulated by the resonator is:

$$W = \frac{P Q}{2 π} ,$$

where P is power absorbed in one period, and Q is quality of resonator, and

$$P = \frac{{v}^{2}}{{R}^{2}} ,$$

where V is voltage of electric field into resonator, R is the equivalent resistivity of the resistive film.

Since two reflected waves cannot propagate in the same direction (back to the generator) due to their opposite phases, energy is “pumped” into the volume of the resonator itself. The voltage amplitude in it is much higher than the amplitude of the applied wave (see FIG. 6). The process is stabilized when the power input is balanced by the loss power, since the higher the field level in the resonator, the greater the loss. Particularly this accumulated power is absorbed by the resistive film.

Therefore, the accumulated energy increases the absorption because the voltage grows. The inventors have found that the required P can be realized with any R (not-optimal too) by varying Q. Thus, for usage of low-temperature resistive materials, resistivity should not be very high to avoid the need for high-temperature pastes. On the other hand, the resistivity cannot be chosen very low, because the resonator quality is a function of resistor value. Therefore, optimal resistivity can be chosen with account of all the parameters mentioned above.

Linear size of the resonator patch (3) should be smaller than the size for maximum efficient radiation (<λ/2\sqrt{ε}) to prevent parasitic radiation (ε is the dielectric constant of the PCB substrate, A is the wavelength in free space).

Simulation results demonstrate that the optimal conductivity of the resistive film is about 80 sim/m with a thickness of 10-30 μm. This value corresponds to the impedance of 800-1000 Ohms/□, which corresponds to e.g., Aquadag E material.

Simulation results also demonstrate that the termination load in the power divider according to the present invention provides good mutual isolation of divider arms and low reflection loss of all ports.

In one embodiment, the intermediate slot radiator (2) has a rectangular slot. To ensure resonant coupling with the exciting feedline (1) and the resonator patch (3), the intermediate slot radiator (2) has the following geometric dimensions: length ˜λ/2\sqrt{ε}, width ˜λ/10\sqrt{ε}. The slot width is often limited by PCB manufacturer's process capabilities.

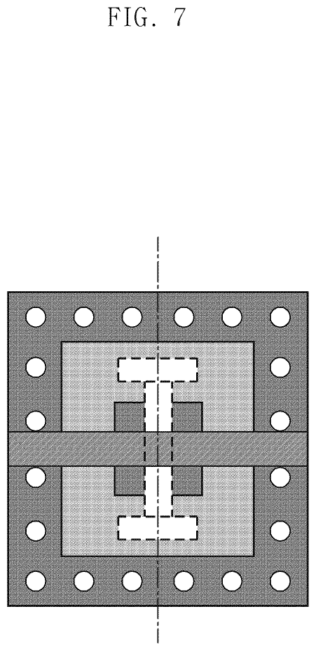

In an alternative embodiment, slot radiator (2) may be H-shaped (H-slot) (see FIG. 7).

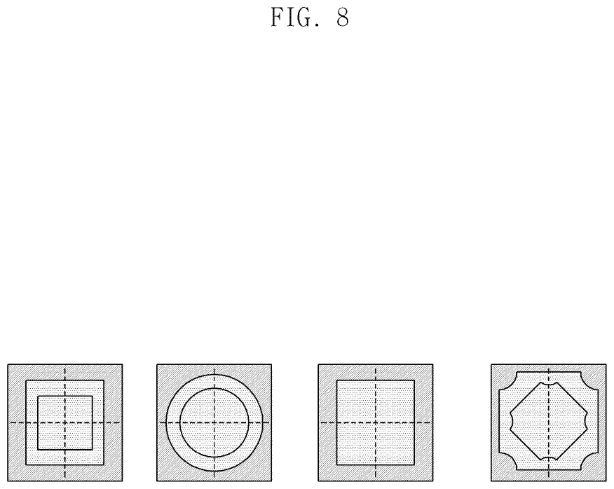

In the embodiment of FIGS. 1 and 2, the resonator patch is square with resistive film filling the gap around its perimeter. It is worth noting, however, that in alternative embodiments, resonator patch and its surrounding gap may have different shapes, e.g., round patch with annular gap, round patch with square gap, square patch with slot in the center and square gap, and other shapes that may positively affect the energy absorption efficiency and provide a more broadband solution (see FIG. 8).

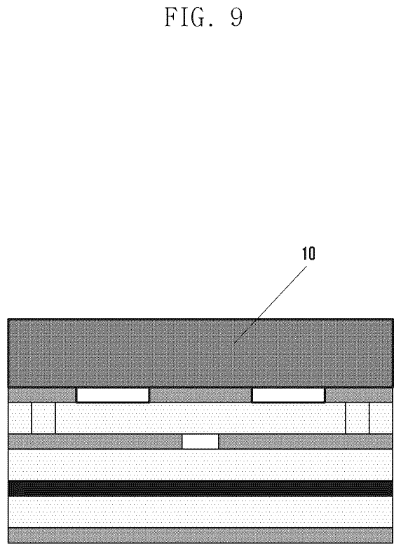

In another alternative embodiment illustrated in FIG. 9, the gap in the power absorbing element is filled with air instead of resistive film (4), and a bulky radio-absorbing dielectric (10) with high dielectric or magnetic losses (e.g., tg δ≥0.7) is used to absorb the energy, a layer of which is applied over the outer PCB layer. Therefore, the power absorbing element includes a resonator patch, a metal layer coplanar with the resonator patch, and a bulky radio-absorbing material deposited over the resonator patch and the coplanar metal layer. In the embodiment, energy is transferred via a feedline (1) and an intermediate slot radiator (2) to a resonator patch (3), radiated by the patch (3), and absorbed by the bulky radio-absorbing material (10). In contrast to the resistive film embodiment, where the resonator patch (3) is a low-Q, relatively small field amplitude resonator, and where energy is absorbed by the film without reaching a significant value, in this embodiment, the resonator patch (3) is a high-Q resonator (due to the absence of resistive film and associated losses). In this case, energy can be transformed by radiation only. As a result, a radiation field is formed, and the radiated power is absorbed by the radio-absorbing material (10), which has high losses. There occurs spatial absorption of radiated energy and release of energy in the form of heat. The greater the material (10) thickness, the higher the parasitic power absorption rate.

To ensure energy radiation by the resonator patch, the patch should be sized for maximum radiation efficiency (˜λ/2\sqrt{ε}), and low loss. This provides high Q factor of the resonator.

This embodiment is simpler in manufacture because instead of precisely applying a resistive film (4) around each resonator patch (3), the entire surface is coated with a bulky radio-absorbing material (10). The radio-absorbing material is chosen to have required radiation absorption characteristics in the millimeter and sub-millimeter range. For example, foamy flexible absorber Eccosorb HR180620 can be used as the bulky radio-absorbing material.

In this embodiment, the termination load can be free from a resonator patch (3). Then, the power absorbing element comprises a bulky radio-absorbing material (10) deposited on the outer PCB layer on top of the intermediate slot radiator (2), and all the energy radiated by the intermediate slot radiator (2) is absorbed by the bulky radio-absorbing material (10).

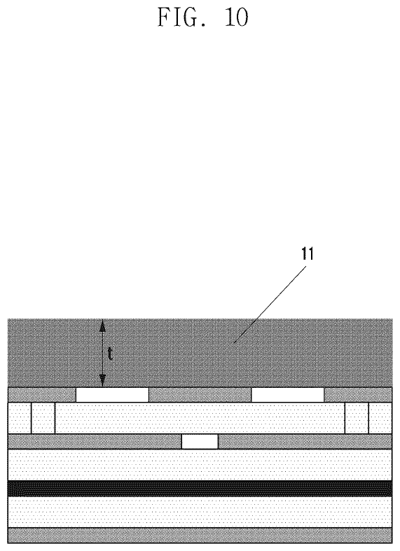

In another embodiment depicted in FIG. 10, instead of the resistive film (4) in the gap for energy absorption in the power absorbing element, a radio-absorbing coating (11) with high dielectric or magnetic losses (e.g., Tg δ≥0.7) is used, which is deposited into the gap and over the outer PCB layer. Thus, the power absorbing element includes a resonator patch, a metal layer coplanar with the resonator patch, and a radio-absorbing coating deposited over the resonator patch and the coplanar metal layer and adapted to absorb energy radiated by the resonator patch. The energy absorption principle in this termination load embodiment is similar to that of the embodiment with the bulky radio-absorbing material. An example of a radio-absorbing coating can be a radio-absorbing paint (e.g., MF-500 Urethane broadband MagRAM coating) or a radio-absorbing adhesive (e.g., ZIPSIL 720 RPM-E). With such coating, a thicker layer is required to absorb energy compared to the resistive film (e.g., for a paint with tg δ=0.7, the radio-absorbing coating thickness of t>0.4 mm is required). This embodiment is also simpler in manufacture since as it does not require precise deposition of resistive film around each resonator patch (3). Much less stringent requirements can be imposed on the deposition of radio-absorbing coating compared to the deposition of resistive film.

In this embodiment, the termination load can be made without a resonator patch (3). The power absorbing element includes radio-absorbing coating (11) applied to the outer PCB layer on top of the intermediate slot radiator and adapted to absorb energy radiated by the intermediate slot radiator (2), and all the energy radiated by the intermediate slot radiator (2) is absorbed by the radio-absorbing coating (11).

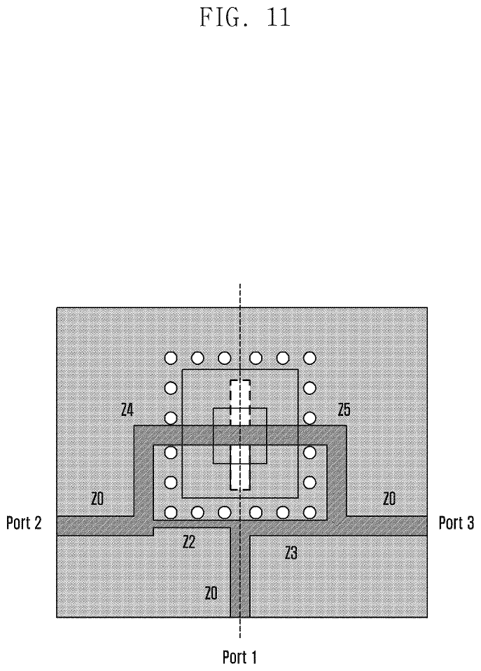

In one more embodiment shown in FIG. 11, a power divider is designed for non-uniform power distribution due to its asymmetrical structure.

To provide power ratio A=P2/P3, where P2 is signal power on port 2, and P3 is signal power on port 3, the power divider branches should have impedances:

$$\begin{matrix}Z 2 = \frac{1 + A}{\sqrt{2} A} Z 0 , \\ Z 3 = \frac{1 + A}{\sqrt{2}} Z 0 , \\ Z 4 = Z 5 = \sqrt{2} * Z 0 ,\end{matrix}$$

where Z4 and Z5 are impedance values of the main divider branches, Z2 and Z3 are impedance values of the additional divider branches.

Similarly to other embodiments, the length of main divider branches is ˜λ_{ε}/4 and the length of additional divider branches is ˜λ_{ε}/2. Here, branch impedance is set by specifying the appropriate branch width. In this embodiment, although the termination load is symmetrical, the power divider as a whole has an asymmetrical structure due to the difference in the width of the divider main branches.

To suppress parasitic waves propagating in the PCB dielectric (9), in some cases it is advisable to shield the termination load (8) structure by a plurality of interlayer plated holes (metal pins, VIA) (7) disposed around its perimeter provided the design dimensions allow. Distance between VIAs should not exceed approximately λ/4\sqrt{ε}. In the exemplary embodiment of FIGS. 2A and 2B, VIAs (7) connect said coplanar metal layer (5) and the ground layer in which the slot radiator is placed (2).

The termination load (8) in the power divider according to the present invention is also designed to absorb parasitic signals caused by phase distortions due to signal reflections from non-uniformities.

Therefore, the present invention provides a simple, reliable and compact power divider that does not require high assembly precision. When using the power divider in an antenna array, including mm-wave range, energy of parasitic signals is effectively absorbed, thereby ensuring low side lobes level of the radiation pattern and a high protection factor, which has a positive effect on the antenna array efficiency (speed, range and reliability of signal transmission).

The power divider can also be used in other microelectronic devices: electrically controlled attenuators, discrete phase shifters, power amplifiers, frequency isolation devices, etc.

The power divider of the present invention is compatible with AiP (Antenna-in-Package) technology.

The present invention can find application in 5G (28 GHz), WiGig (60 GHz), Beyond 5G (60 GHz) and 6G (sub-terahertz) wireless communication systems, short-range communication systems (60 GHz, NFC), automotive radars (60 GHz, 80 GHz) for autonomous vehicles, wireless data transmission between different modules in modular devices, between components in electronic devices, etc.

It should be understood that although the terms such as “first”, “second”, “third” and the like may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, a first element, component, region, layer, or section may be referred to as a second element, component, region, layer, or section without departing from the scope of the present invention. As used herein, the term “and/or” includes any and all combinations of one or more of the respective listed items. Elements mentioned in the singular do not exclude the plurality thereof, unless otherwise specified.

Functionality of an element specified in the description or claims as a single element may be practiced by means of several components of the device, and conversely, functionality of elements specified in the description or claims as several separate elements may be practiced by means of a single component.

Embodiments of the present invention are not limited to the embodiments described herein. Other embodiments of the invention that do not go beyond the idea and scope of this invention will be apparent to those skilled in the art on the basis of the information set forth in the description and knowledge of the art.

Elements mentioned in the singular do not exclude the plurality of elements, unless otherwise specified.

Those skilled in the art should appreciate that the essence of the invention is not limited to a particular software or hardware, and therefore any existing software and hardware can be used for implementing the invention. For example, hardware may be implemented in one or more application specific integrated circuits, digital signal processors, digital signal processing devices, programmable logic devices, field-programmable gate arrays, processors, controllers, microcontrollers, microprocessors, electronic devices, other electronic units configured to perform the functions described in this disclosure, a computer or a combination thereof.

While exemplary embodiments have been described and shown in the accompanying drawings, it should be understood that such embodiments are illustrative only and not intended to limit the broader invention, and that the invention should not be limited to the particular arrangements and structures shown and described, since various other modifications may be apparent to those skilled in the art.

Features recited in various dependent claims, as well as embodiments disclosed in various parts of the description, can be combined to achieve beneficial effects, even if the possibility of such a combination is not explicitly disclosed.

Although the present disclosure has been described with various embodiments, various changes and modifications may be suggested to one skilled in the art. It is intended that the present disclosure encompass such changes and modifications as fall within the scope of the appended claims.

What is claimed is:

1. An mm-wave signal power divider implemented on a printed circuit board (PCB) and including an input arm, two output arms and a termination load embedded into the PCB,
wherein each power divider arm is located on inner PCB layer and includes a feedline having impedance Z0;
each power divider output arm further includes a main power divider branch and an additional power divider branch;
the main power divider branch connects the input arm feedline and the output arm feedline and has a length multiple of
$$∼ \frac{{λ}_{ε}}{4} ,$$
where λ_{ε} is a wavelength in the feedline of the mm-wave signal power divider, with account of dielectric parameters of the PCB;
the additional power divider branch extends from a point of connection of the main power divider branch with the output arm feedline to a symmetry plane of the termination load and has a length multiple of
$$∼ \frac{{λ}_{ε}}{2} ;$$
additional power divider branches are connected in the symmetry plane of the termination load;
the termination load is disposed above an exciting feedline, which represents a portion of the connected additional power divider branches, and includes an intermediate slot radiator placed orthogonally to the exciting feedline between a layer where the exciting feedline is located and a outer PCB layer, and a power absorbing element located on the outer PCB layer; and
the symmetry plane of the termination load is arranged longitudinally to the intermediate slot radiator;
the exciting feedline and the intermediate slot radiator are coupled via electromagnetic coupling.

2. The power divider of claim 1, wherein the power absorbing element includes a resonator patch, a resistive material surrounding the resonator patch, a metal layer coplanar with the resonator patch, and wherein the resistive material fills a gap between the resonator patch and the coplanar metal layer, and the resonator patch and the intermediate slot radiator are coupled via electromagnetic coupling.

3. The power divider of claim 2, wherein the resistive material in the gap between the resonator patch and the coplanar metal layer is a resistive film.

4. The power divider of claim 2, wherein a size of the resonator patch is less than
$$∼ \frac{λ}{2 \sqrt{ε}} ,$$
where ε is a permittivity of a substrate of the PCB, and λ is a wavelength in free space.

5. The power divider of claim 1, wherein the power absorbing element includes a resonator patch, a metal layer coplanar with the resonator patch, and a bulky radio-absorbing material or radio-absorbing coating applied on top of the resonator patch and the coplanar metal layer and configured to absorb energy radiated by the resonator patch, wherein the resonator patch and the intermediate slot radiator are coupled via electromagnetic coupling.

6. The power divider of claim 5, wherein the radio-absorbing coating is a radio-absorbing paint or a radio-absorbing adhesive.

7. The power divider of claim 5, wherein a size of the resonator patch is
$$∼ \frac{λ}{2 \sqrt{ε}} .$$

8. The power divider of claim 1, wherein the power absorbing element includes a bulky radio-absorbing material or radio-absorbing coating applied to the outer PCB layer above the intermediate slot radiator and configured to absorb energy radiated by the intermediate slot radiator.

9. The power divider of claim 8, wherein the radio-absorbing coating is a radio-absorbing paint or a radio-absorbing adhesive.

10. The power divider of claim 1, wherein the termination load is surrounded over a perimeter by a plurality of interlayer plated holes (VIA), a distance between which does not exceed
$$∼ \frac{λ}{4 \sqrt{ε}} .$$

11. The power divider of claim 1, wherein the length of the main power divider branches is
$$∼ \frac{{λ}_{ε}}{4} ,$$
and the length of the additional power divider branches is
$$∼ \frac{{λ}_{ε}}{2} .$$

12. The power divider of claim 1, wherein the power divider is symmetrical with respect to the symmetry plane of the termination load.

13. The power divider of claim 11, wherein each additional power divider branch has impedance Z0, and the termination load has impedance 2*Z0.

14. The power divider of claim 1, wherein the intermediate slot radiator is in a form of a rectangular slot with length
$$∼ \frac{λ}{2 \sqrt{ε}}$$
and width
$$∼ \frac{λ}{10 \sqrt{ε}} .$$

15. The power divider of claim 1, wherein the intermediate slot radiator is H-shaped.

16. The power divider of claim 1, wherein the power divider is configured to provide non-uniform power distribution with a ratio A=P2/P3, where P2 and P3 are powers of signals on the power divider output arms, and the power divider branches have impedance values:
$$\begin{matrix}Z 2 = \frac{1 + A}{\sqrt{2} A} Z 0 , \\ Z 3 = \frac{1 + A}{\sqrt{2}} Z 0 , \\ Z 4 = Z 5 = \sqrt{2} * Z 0 ,\end{matrix}$$
where Z4 and Z5 are the impedance values of the main power divider branches, and Z2 and Z3 are the impedance values of the additional power divider branches;
wherein the impedance of the power divider branches is set by specifying a width of the power divider branches.

17. An antenna array including antenna elements connected through a power distribution system comprising mm-wave signal power dividers, with a control circuit, wherein each mm-wave signal power divider is implemented on a printed circuit board (PCB) and includes an input arm, two output arms and a termination load embedded into the PCB,
wherein each power divider arm is located on inner PCB layer and includes a feedline having impedance Z0;
each power divider output arm further includes a main power divider branch and an additional power divider branch;
the main power divider branch connects the input arm feedline and the output arm feedline and has a length multiple of
$$∼ \frac{{λ}_{ε}}{4} ,$$
where λ_{ε} is a wavelength in the feedline of the mm-wave signal power divider, with account of dielectric parameters of the PCB;
the additional power divider branch extends from a point of connection of the main power divider branch with the output arm feedline to a symmetry plane of the termination load and has a length multiple of
$$∼ \frac{{λ}_{ε}}{2} ;$$
additional power divider branches are connected in the symmetry plane of the termination load;
the termination load is disposed above an exciting feedline, which represents a portion of the connected additional power divider branches, and includes an intermediate slot radiator placed orthogonally to the exciting feedline between a layer where the exciting feedline is located and the outer PCB layer, and a power absorbing element located on the outer PCB layer;
the symmetry plane of the termination load is arranged longitudinally to the intermediate slot radiator; and
the exciting feedline and the intermediate slot radiator are coupled via electromagnetic coupling.

18. The antenna array of claim 17, wherein the power absorbing element includes a resonator patch, a resistive material surrounding the resonator patch, a metal layer coplanar with the resonator patch, and wherein the resistive material fills a gap between the resonator patch and the coplanar metal layer, and the resonator patch and the intermediate slot radiator are coupled via electromagnetic coupling.

19. The antenna array of claim 18, wherein the resistive material in the gap between the resonator patch and the coplanar metal layer is a resistive film.

20. The antenna array of claim 17, wherein the power absorbing element includes a resonator patch, a metal layer coplanar with the resonator patch, and a bulky radio-absorbing material or radio-absorbing coating applied on top of the resonator patch and the coplanar metal layer and configured to absorb energy radiated by the resonator patch, wherein the resonator patch and the intermediate slot radiator are coupled via electromagnetic coupling.
